(19) United States
(12) Patent Application Publication
(10) Pub. No.: US 2013/0214293 A1
(43) Pub. Date: Aug. 22, 2013

(54) MICRO OPTICAL DEVICE

(71) Applicants: Monuko Duplessis, Pretoria (ZA); Alfons Willi Bogalecki, Munchen (ZA)

(72) Inventors: Monuko Duplessis, Pretoria (ZA); Alfons Willi Bogalecki, Munchen (ZA)

(73) Assignee: Insiava(PTY)Limited, Pretoria (ZA)

(21) Appl. No.: 13/810,809

(22) PCT Filed: Jul. 8, 2011
(86) PCT No.: PCT/IB11/53046

§ 371 Date: Apr. 1, 2013

(30) Foreign Application Priority Data
Jul. 19, 2010 (ZA) 2010/05125

(51) Int. Cl. H01L 33/20; H01L 31/173; H01L 31/167

(52) U.S. Cl. CPC H01L 33/20; H01L 31/167; H01L 31/173
USPC 257/84; 257/86; 257/80

(57) ABSTRACT

A micro optical device 10 comprises a body 12. The body comprises a movable member 14, which is moveable relative to another part 26 of the body. An optical element, such as an optical source 16, is provided on or within the movable member. The moveable member may be subjected to a parameter, such as mass, to be sensed and by monitoring at detector 22 changes of an optical signal emitted by the optical source, the parameter may be monitored.

### INTRODUCTION AND BACKGROUND

This invention relates to micro optical devices and more particularly to a micro optical sensor and a method of sensing a parameter.

Cantilever-type devices are used in micro sensors. For example, in an accelerometer, displacement or deflection of a cantilever beam may be an indication of acceleration to be sensed or monitored. As another example, in a biological lab-on-chip application, deflection of the cantilever beam may be measured as an indication of a biological mass deposited on the cantilever beam.

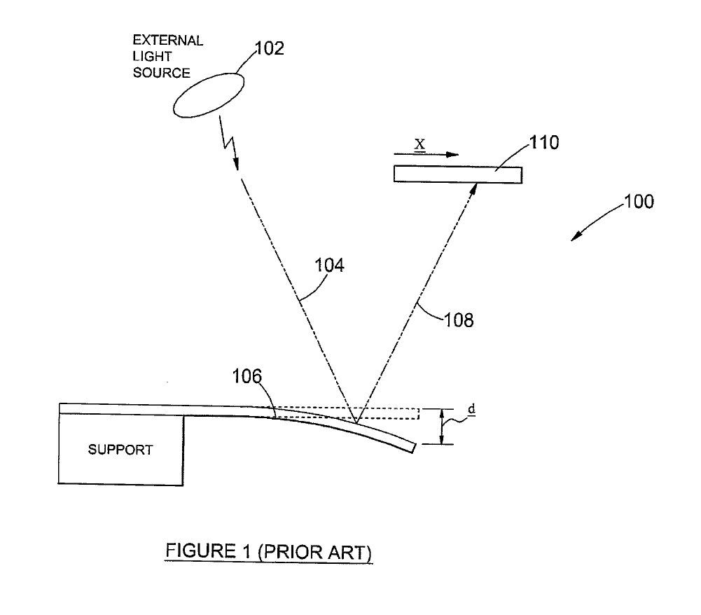

As shown in FIG. 1 of the accompanying diagrams, it is known to measure the deflection of the cantilever beam by an optical arrangement comprising a light source externally of the cantilever, from which a beam of light is shone onto the cantilever beam. The light reflected from the cantilever beam is collected by an external position sensitive optical detector, for example a CCD or photodiode array of linear pixels. In this specification, the term “position sensitive optical detector” is used to denote an optical detector that is sensitive to the position of illumination of an impinging optical signal upon a surface of the detector. Using this arrangement, an impinging light spot displacement x on the detector is a function of the beam deflection distance d. Although with such an arrangement it is possible to measure the deflection distance d and therefore a force exerted on the cantilever beam, these arrangements are not suitable for some applications for at least one of various reasons including cost, reliability problems, large volume mass manufacture complexities and signal processing difficulties.

### OBJECT OF THE INVENTION

Accordingly, it is an object of the present invention to provide a micro optical device and a method of sensing a parameter with which the applicants believe at least some of the aforementioned disadvantages may at least be alleviated or which may provide a useful alternative for the known devices and methods.

### SUMMARY OF THE INVENTION

According to the invention there is provided a micro optical device comprising:
a body;
the body comprising a movable member which is moveable relative to another part of the body; and
an optical element provided on or within the movable member.

The movable member may comprise a diaphragm or membrane, for example. In a preferred embodiment of the invention, the movable member comprises a cantilever beam.

The other part of the body may comprise a base and the cantilever beam may be supported on the base by a support, to overhang the base.

The movable member may be made from any suitable material and in a preferred embodiment, the movable member is at least partially made from a semiconductor material.

The base and movable member may be integrally formed from the semiconductor material.

The semiconductor material may be a direct band-gap semiconductor material. Alternatively, the semiconductor material may be an indirect band-gap semiconductor material. The indirect band-gap semiconductor material may comprise silicon.

The base may comprise bulk silicon, the cantilever beam may comprise a first part of a layer of silicon provided on the bulk silicon by a silicon on insulator (SOI) technology and the support may comprise a first part of an intermediate isolation layer provided by the SOI technology.

The optical element may be mounted in or on the movable member, but preferably is integrally formed with the movable member.

The optical element may comprise an optical detector.

Alternatively, the optical element may comprise an optical source such as an electroluminescent device (for example a semiconductor pn junction or a thermal element) or a device comprising a photo-luminescent material which emits light after having been excited by another optical source. The light source used to excite the photo-luminescent material may be integrated with the body or may be external thereto.

In a preferred embodiment, the cantilever beam is made of a semiconductor material and the optical source comprises at least one junction between a first part of the movable member of a first doping kind and a second part of the movable member of a second doping kind. The first doping kind may be p-type and the second doping kind may be n-type.

In one embodiment, the cantilever beam may comprise a first part and a second part extending away from the support to meet at the at least one junction towards corresponding distal ends of the first and second parts of the movable member.

The device may comprise an optical detector for cooperating with the optical source.

The optical detector may be provided on a separate body. In other embodiments, the optical detector may be integrally formed with the body.

The device may comprise an optical mirror between the optical source and the optical detector. The optical mirror may be external of the body or may form part of the body and the optical detector may be provided on the body. The optical detector may be provided in the bulk silicon.

In another embodiment, the optical detector may comprise a second part of the SOI layer of silicon and may be supported on the bulk silicon by a second part of the intermediate isolation layer.

In yet other embodiments, the device may comprise an optical path extending in one straight line between the optical source and the optical detector.

The optical detector may be provided in the bulk silicon. The optical detector may be provided laterally spaced from the cantilever beam. Alternatively, the cantilever beam may extend over the optical detector.

In another embodiment, the optical detector may comprise a second part of the SOI layer of silicon and may be supported on the bulk silicon by a second part of the intermediate isolation layer.

The optical detector may comprise a position sensitive detector. In addition or alternatively, the optical detector may comprise a spectrally sensitive optical detector.

Also included within the scope of the invention is a device comprising a body; the body comprising a movable member which is moveable relative to another part of the body; an optical element provided on the movable member; at least first and second spaced optical waveguides and a controllable power supply connected between the body and the movable member to deform the movable member and thereby to bring a selected one of the at least first and second wave guides into communication with the optical element.

The optical element may comprise any one or both of an optical source and an optical detector.

The at least first and second waveguides may comprise optical fibre.

According to another aspect of the invention there is provided a method of sensing a parameter comprising the steps of:
utilizing an optical source on or within a movable member of a micro body;
subjecting the movable member to a parameter to be sensed; and
monitoring changes of an optical signal emitted by the optical source, to sense the parameter.

The parameter to be sensed may be any parameter that changes at least one of the physical dimensions, shape, configuration and optical characteristics of the movable member and/or the optical source integrated therewith. Parameters that deform or deflect the movable member or otherwise change the direction of emitted light include, but is not limited to, mass, acceleration, gravity, pressure and orientation. Other parameters include physical or chemical parameters that change optical characteristics such as, spectral absorption, transmission, dispersion or reflectivity of the movable member or the integrated optical source.

### BRIEF DESCRIPTION OF THE ACCOMPANYING DIAGRAMS

The invention will now further be described, by way of example only, with reference to the accompanying diagrams wherein:

FIG. 1 is a diagrammatic illustration of a prior art cantilever-type micro optical sensor device;

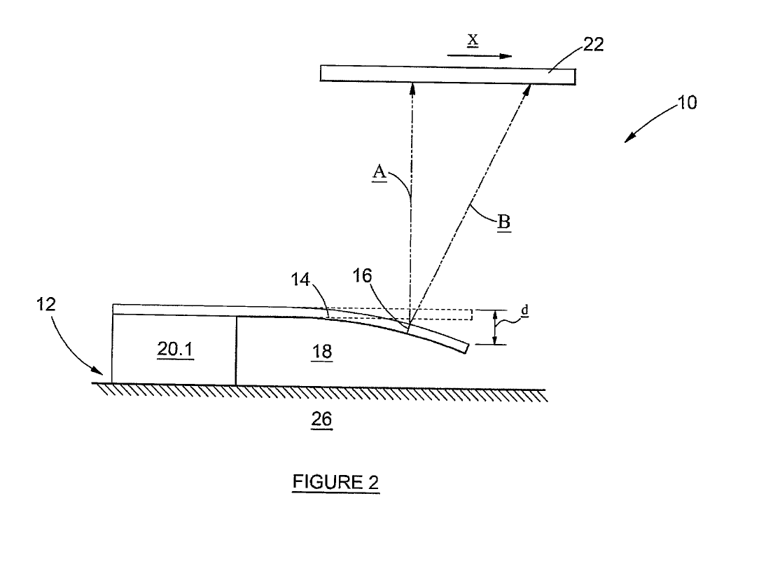

FIG. 2 is a diagrammatic representation of a first example embodiment of a micro optical device according to the invention in the form of a micro optical sensor device;

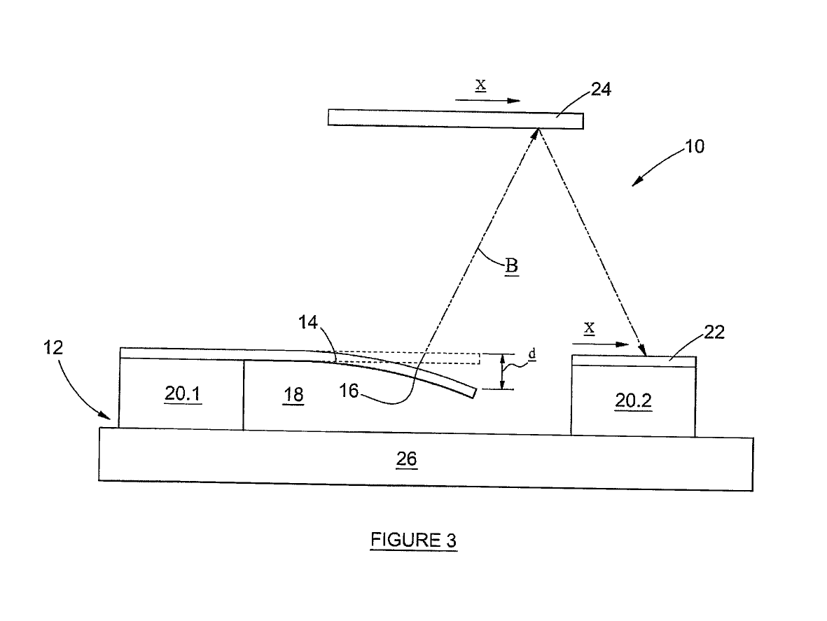

FIG. 3 is a diagrammatic representation of a second example embodiment of the sensor device according to the invention;

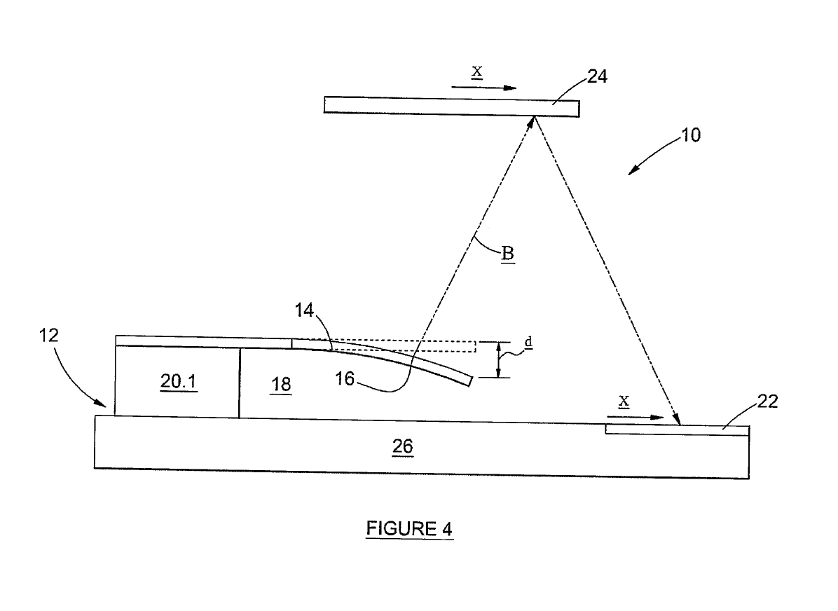

FIG. 4 is a diagrammatic representation of a third example embodiment of the sensor device according to the invention;

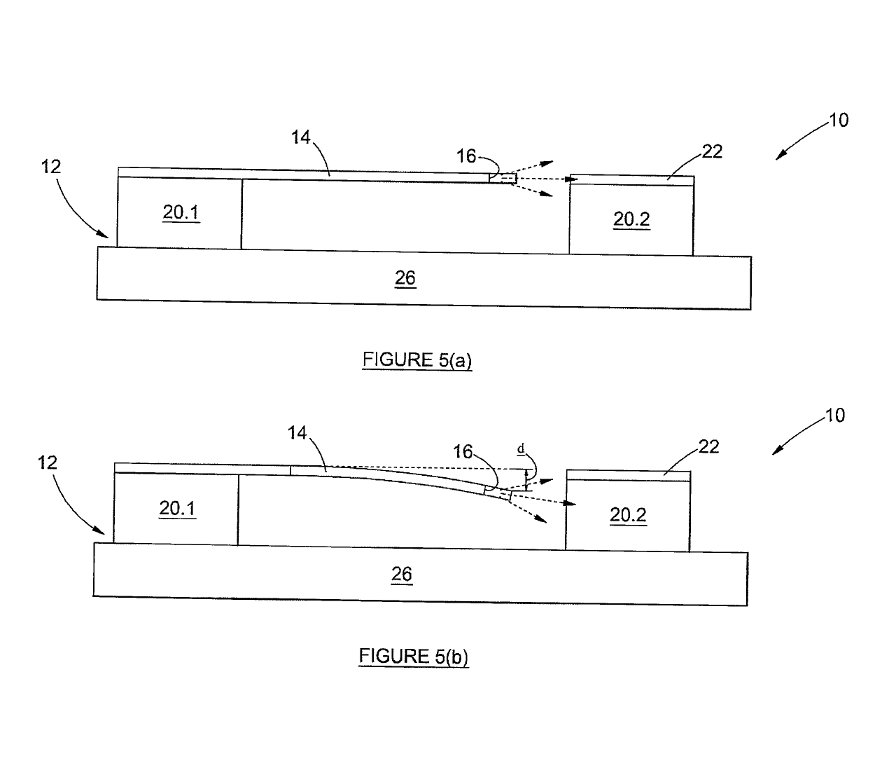

FIG. 5(a) and (b) are diagrammatic representations of a fourth example embodiment of the sensor device according to the invention;

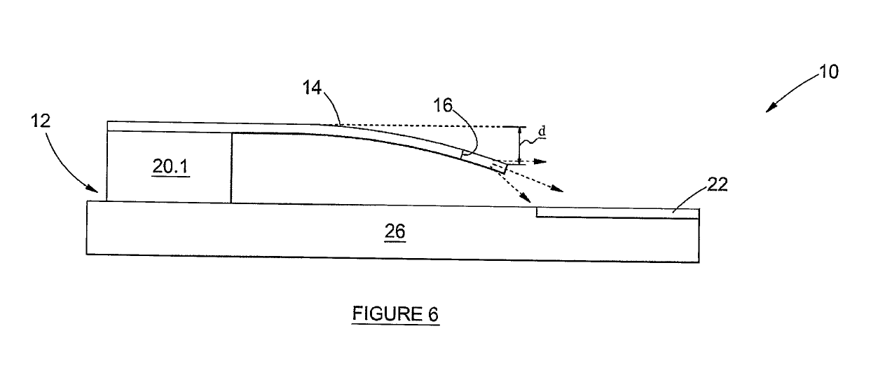

FIG. 6 is a diagrammatic representation of a fifth example embodiment of the sensor device according to the invention;

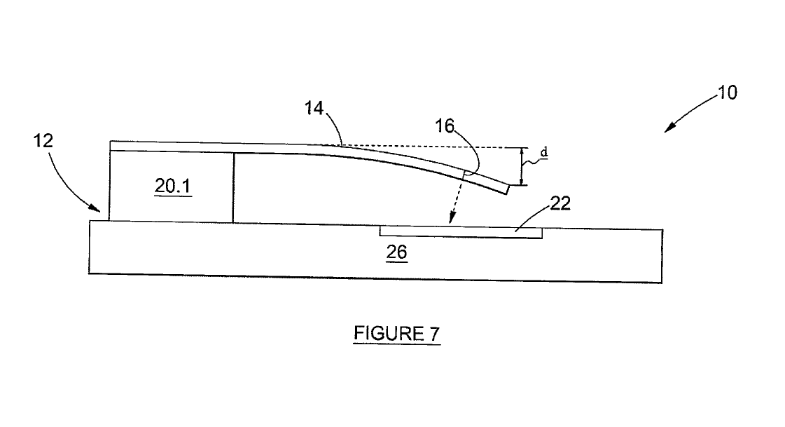

FIG. 7 is a diagrammatic representation of a sixth example embodiment of the sensor device according to the invention;

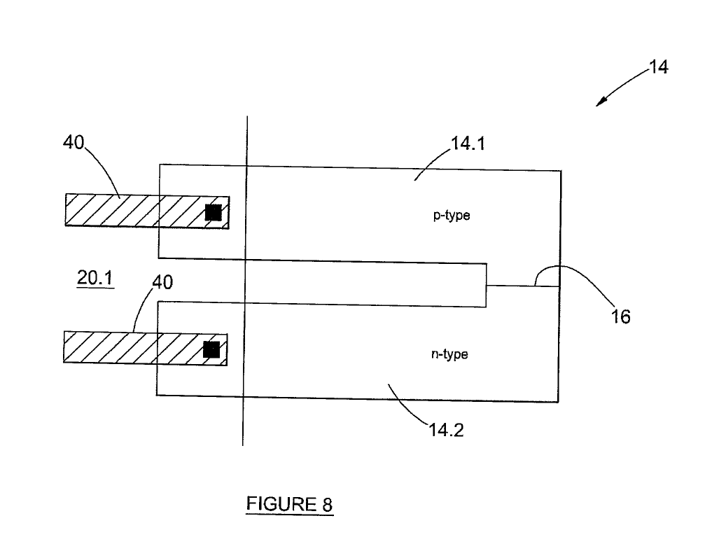

FIG. 8 is a diagrammatic plan view of relevant parts only of an example embodiment of the sensor device according to the invention;

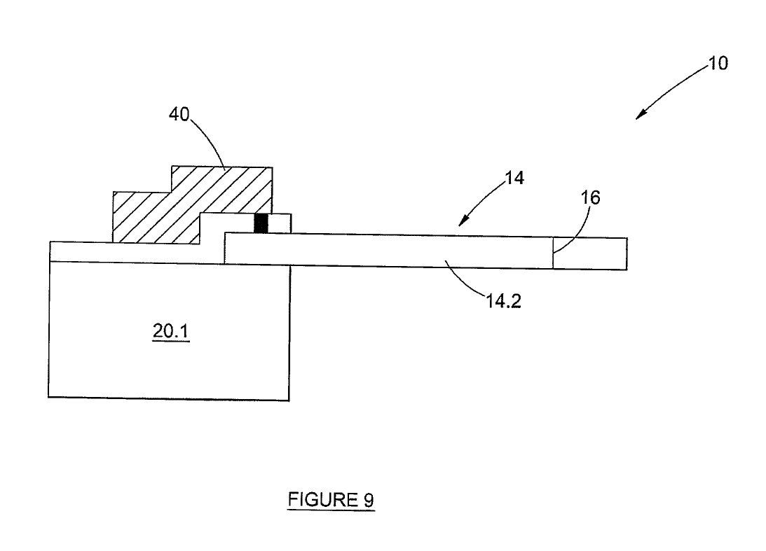

FIG. 9 is a diagrammatic side view of the device in FIG. 8;

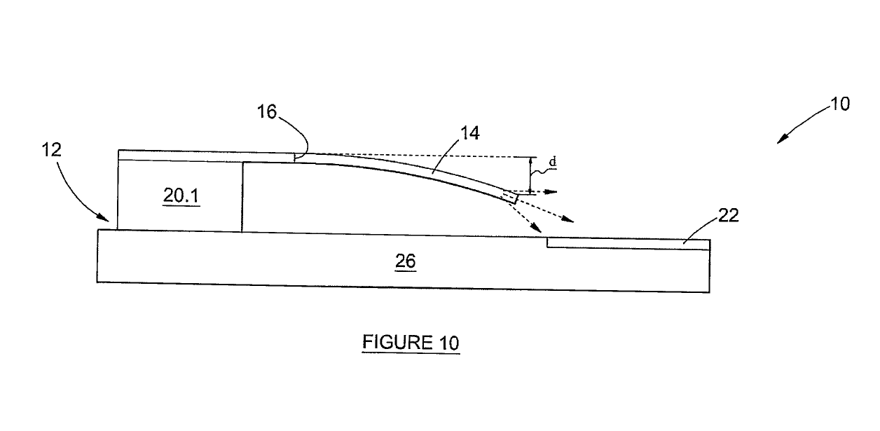

FIG. 10 is a diagrammatic side view of a seventh example embodiment of the sensor device according to the invention; and

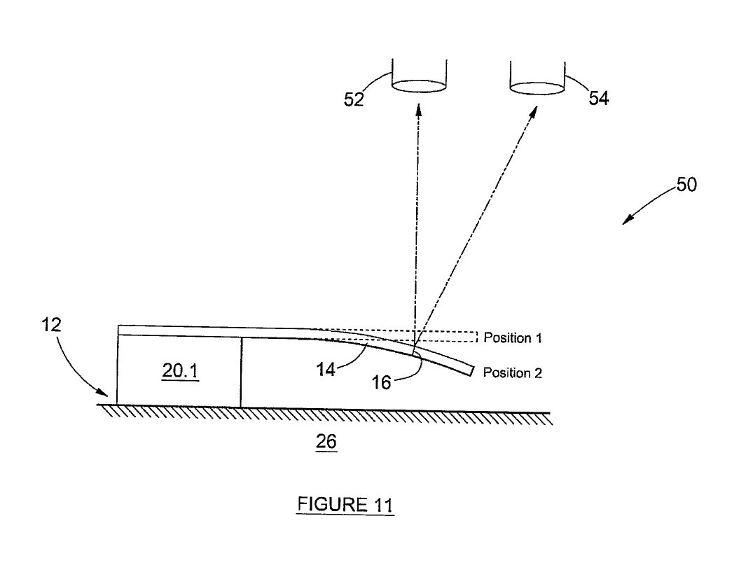

FIG. 11 is a diagrammatic side view of an example embodiment of a micro optical switching device.

### DESCRIPTION OF A PREFERRED EMBODIMENT OF THE INVENTION

In FIG. 1 there is shown a prior art optical sensor arrangement 100 utilizing an external light source 102, from which a beam of light 104 is shone onto a moveable member or cantilever beam 106. The light reflects from the cantilever beam along 108 and is collected by an external position sensitive optical detector 110, for example, a CCD or photodiode array of pixels. An impinging light spot displacement distance x on the detector 110 is a function of the beam deflection distance d.

Referring to FIG. 2, a first example embodiment of a micro optical device according to the invention in the form of a micro optical sensor device is generally designated by the reference numeral 10. The device 10 comprises a body 12 comprising a movable member 14 and an optical element 16 provided on the movable member.

In the example embodiments described herein, the movable member comprises a cantilever beam 14 that is mounted on a base 26 of the body 12 to extend over the base. The moveable member may alternatively comprise a diaphragm or membrane, for example. The optical element 16 may be an optical source, such as an electroluminescent device (for example a thermal element) or a device comprising a photo-luminescent material, which emits light after having been excited by another optical source. The light source used to excite the photo-luminescent material may be integrated with the body or may be external thereto.

However, in the example embodiments herein described, the optical source 16 comprises one or more p-n junctions in a semiconductor material. The p-n junctions may be reverse or forward biased to generate photons, and the semiconductor material may be any direct or indirect band-gap material compatible with the semiconductor manufacturing process utilized. In the case of SOI (silicon on insulator) CMOS technology, the semiconductor material comprises silicon and the cantilever beam 14 comprises a first part of the active silicon layer of the SOI technology and a first part 20.1 of the underlying buried oxide (BOX) layer serves to support the cantilever beam towards one end thereof on the bulk material. The remainder of the BOX is removed or sacrificed at 18, to form the cantilever beam extending over the base of bulk material.

In FIG. 2, the optical signal is generated within the movable part of the cantilever beam 14. The external radiation pattern of the integrated optical source 16 is modified by the deflection of the cantilever beam and the external position sensitive optical detector 22 is able to discriminate between the detected radiation from the cantilever optical source 16 with no force applied to the beam, as at A, and the radiation when a downward force is applied to the beam, as at B. In this way, the beam deflection can be optically measured with the optical source 16 integrated within the cantilever beam 14.

In the example embodiment in FIG. 3, the detector 22 is integrated within the body 12 of a semiconductor integrated circuit. The device 10 of FIG. 3 comprises an external optical mirror 24, which is tilted at a constant angle relative to a fixed part of the cantilever beam 14. The mirror reflects an optical signal emitted from the integral optical source 16 in a moveable part of the beam back to the optical detector 22 forming part of the integrated sensor device. More particularly, the position sensitive optical detector 22 is made in the same semiconductor layer that is used for the cantilever fabrication and is supported on a second part 20.2 of the BOX.

Another example embodiment is shown in FIG. 4. In this embodiment, the position sensitive optical detector 24 is manufactured in the bulk material 26 used in the semiconductor process. In both the embodiments of FIGS. 3 and 4, the output signal of the position sensitive optical detector (as determined by distance x) is a function of the deflection d of the cantilever beam.

Referring now to the example embodiment in FIGS. 5(a) and 5(b), the light from the integrated optical source 16 is collected by an integrated optical detector 22 on the same level above the base 26 as the cantilever beam. The optical detector output signal varies with deflection distance d, since the intensity of the light from the light source 16 being absorbed by the optical detector is a function of the deflection distance d. Hence, in the embodiment of FIGS. 5(a) and (b) the optical detector 22 needs not be a position sensitive detector.

As shown in the example embodiment in FIG. 6, the optical detector 22 is manufactured in the bulk material 26, to be laterally spaced from the cantilever beam 14. In this embodiment, the optical detector 22 is preferably a position sensitive device.

In other embodiments and as illustrated in FIG. 7, the optical detector 22 is placed directly underneath the integrated light source 16. Again, the optical detector 22 is preferably a position sensitive device.

In the example embodiment of FIGS. 8 and 9, the cantilever beam 14 comprises first and second elongate parts 14.1 and 14.2. The first part comprises material of a first doping kind, such as p-type, and the second part comprises material of a second doping kind, such as n-type. The parts 14.1 and 14.2 extend in spaced relation parallel to one another and meet in a pn-junction 16 at a distal end of the cantilever beam. It is believed that this structure may have some advantages, such as that no metal lines or tracks need to form part of the cantilever beam. Metal contacts 40 may be placed on the support 20.1 and the optical source 16 may be placed at a point where the deflection distance d (into or out of the paper) is at a maximum or close to a maximum. In the fully integrated devices shown in FIGS. 5(a), (b), 6 and 7, the cantilever beam configuration 14 shown in FIGS. 8 and 9 is expected to limit optical absorption within the cantilever beam itself, thus ensuring more optical power incident on the optical detector 22. Furthermore, the configuration may result in the optical source 16 being located very close to the optical detector 22, resulting in good coupling between the optical source 16 and optical detector 22.

It is known that mechanical stress (tensile or compressive) may alter the energy band structure of semiconductor materials, for example change the forbidden energy gap value between the conduction and valence bands of the material. Since the emission spectrum of semiconductor light emitting devices depends on the energy gap and energy band structure, in the device 10 in FIG. 10, the optical source 16 is placed within the body of the cantilever beam 14 where mechanical stresses occur. The emission spectrum of the optical source 16 is used to measure the deflection distance d. More particularly, the light generation region 16 is placed on the cantilever beam 14 where sufficient mechanical stress is experienced and a spectrally sensitive detector 22 detects changes in spectral emission (for example changes in wavelength of peak emission), which are an indication of the deflection distance d of the beam 14.

In FIG. 11 there is shown an example embodiment of a micro optical switching device 50. The optical element 16 is provided on the cantilever beam 14. By applying an electrostatic potential between the cantilever beam 14 and the bulk material 26, the cantilever beam position may be switched between at least two positions, designated Position 1 and Position 2. This enables the optical element 16 selectively to be brought into optical communication or coupling with a selectable one of first waveguide 52 and second waveguide 54. The optical element may comprise an optical source and/or optical detector. The waveguides, which are not limited to two, may serve as input and/or output waveguides. The waveguides may comprise optical fibre.

1. A micro optical device comprising:
a body;
a movable member on the body which is moveable relative to the body, at least part of the moveable member being made from an indirect band-gap semiconductor material; and
an optical source which is formed from the indirect band-gap semiconductor material integrally with the at least part of the movable member.

2. A device as claimed in claim 1 wherein the movable member comprises a cantilever beam.

3. A device as claimed in claim 2 wherein the other part of the body comprises a base and wherein the cantilever beam is supported on the base by a support, to overhang the base.

4. (canceled)

5. A device as claimed in claim 3, wherein the base and movable member are integrally formed from the indirect band-gap semiconductor material.

6. (canceled)

7. (canceled)

8. A device as claimed in claim 1 wherein the indirect band-gap semiconductor material comprises silicon.

9. A device as claimed in claim 3 wherein the base comprises bulk silicon, wherein the cantilever beam comprises a first part of a layer of silicon provided on the bulk silicon by a silicon on insulator technology and wherein the support comprises a first part of an isolation layer provided by the silicon on insulator technology.

10. (canceled)

11. (canceled)

12. (canceled)

13. A device as claimed in claim 1 wherein the optical source comprises at least one junction between a first part of the movable member of a first doping kind and a second part of the movable member of a second doping kind.

14. A device as claimed in claim 13 wherein the cantilever beam comprises a first part and a second part extending away from the support to meet at the at least one junction towards corresponding distal ends of the first and second parts of the movable member.

15. A device as claimed in claim 1 further comprising an optical detector for cooperating with the optical source.

16. A device as claimed in claim 15 wherein the optical detector is provided on a separate body.

17. A sensor as claimed in claim 15 wherein the optical detector is integrally formed with the body.

18. A device as claimed in claim 15 comprising an optical mirror between the optical source and the optical detector.

19. A device as claimed in claim 18 wherein the optical mirror is external of the body and wherein the optical detector is provided on the body.

20. A device as claimed in claim 19 wherein the base comprises bulk silicon, and wherein the device further comprises an optical detector which is provided in the bulk silicon.

21. A device as claimed in claim 19 wherein the base comprises bulk silicon, and wherein the device further comprises an optical detector which comprises a second part of the layer of silicon and is supported on the bulk silicon by a second part of the isolation layer.

22. A device as claimed in claim 15 comprising an optical path extending in one straight line between the optical source and the optical detector.

23. A device as claimed in claim 22 wherein the base comprises bulk silicon, and wherein the optical detector is provided in the bulk silicon.

24. A device as claimed in claim 23 wherein the optical detector is provided laterally spaced from the cantilever beam.

25. A device as claimed in claim 23 wherein the cantilever beam extends over the optical detector.

26. A device as claimed in claim 22 wherein the base comprises bulk silicon, and wherein the optical detector comprises a second part of the layer of silicon and is supported on the bulk silicon by a second part of the isolation layer.

27. A device as claimed in claim 15 wherein the optical detector comprises a position sensitive optical detector.

28. A device as claimed in claim 15 wherein the optical detector comprises a spectrally sensitive optical detector.

29. A device as claimed in claim 1 comprising at least first and second optical waveguides and a controllable power supply connected between the other part of the body and the movable member to deform the movable member and thereby selectively to bring a selected one of the at least first and second waveguides into communication with the optical source.

30. (canceled)

31. (canceled)

32. A device as claimed in claim 29 wherein the at least first and second waveguides comprise optical fibre.

33. (canceled)
